(19) United States
(12) Patent Application Publication
(10) Pub. No.: US 2010/0184284 A1
(43) Pub. Date: Jul. 22, 2010

(54) Method of Manufacturing Semiconductor Memory Device

(75) Inventor: Sung Soon Kim, Seoul (KR)

Correspondence Address: MARSHALL, GERSTEIN & BORUN LLP, 233 SOUTH WACKER DRIVE, 6300 WILLIS TOWER, CHICAGO, IL, 60606-6357, US

(73) Assignee: HYNIX SEMICONDUCTOR INC., Incheon-si (KR)

(21) Appl. No.: 12/648,842

(22) Filed: Dec. 29, 2009

(30) Foreign Application Priority Data
Jan. 21, 2009 (KR) 10-2009-0005087

(51) Int. Cl. H01L 21/28

(52) U.S. Cl. 438/593; 257/E21.209

(57) ABSTRACT

A method of manufacturing a semiconductor memory device comprises providing a semiconductor substrate, forming gate lines over the semiconductor substrate, wherein each of the gate lines has a stack structure comprising an upper layer having a blocking layer formed on a polysilicon layer, forming a dielectric interlayer between the gate lines such that sides of the polysilicon layers of the gate lines are exposed, forming a metal layer on an entire surface of the dielectric interlayers, the blocking layers, and the polysilicon layers, causing the polysilicon layers in contact with the metal layer to react with the metal layer and undergo a phase change and become silicide layers, and removing the unreacted metal layer.

### CROSS-REFERENCE TO RELATED APPLICATION

Priority to Korean patent application number 10-2009-0005087 filed on Jan. 21, 2009, the entire disclosure of which is incorporated by reference herein, is claimed.

### BACKGROUND

An embodiment relates generally to a method of manufacturing a semiconductor memory device and, more particularly, to a method of manufacturing a semiconductor memory device including a silicide layer.

A nonvolatile memory device of semiconductor memory devices includes a floating gate for storing data and a control gate for transferring driving voltages. In particular, the control gate has a direct influence on the speed of the program operation because it generates coupling.

Meanwhile, with an increase in the degree of integration of semiconductor devices, the critical dimension and the gap of gate lines as well as memory cells are narrowed. Resistance can be increased with a reduction in the critical dimension of the gate lines. Thus, the control gate has a stack structure of a polysilicon layer and a metal layer. A tungsten layer has been chiefly used as the metal layer, but this is problematic in that tungsten deteriorates resistance characteristics because of abnormal oxidization. To improve the resistance characteristic, a silicide layer may be used instead of a tungsten layer.

The silicide layer is formed by forming a metal layer on a polysilicon layer and then performing an annealing process such that metal ions from the metal layer are diffused into the polysilicon layer, causing a phase change. The remaining, unreacted metal layer is then removed. For example, if a cobalt (Co) layer is used as the metal layer, the silicide layer becomes a cobalt silicide (CoSi₂) layer.

To form a CoSi₂ layer, two silicon (Si) ions are necessary for a single Co ion. As the critical dimension of a gate line is reduced resulting from the high degree of integration of semiconductor devices, the absolute amount of Si ions is decreased. In this case, the most significant problem is that, if the amount of cobalt (Co) deposited is high or the deposition itself of cobalt (Co) is asymmetric when a Co layer is formed, a reaction of Co ions and Si ions is irregularly generated in all the gate lines. Consequently, the gate lines finally formed after the Co layer that remains unreacted is removed are bent or broken.

To suppress this phenomenon, a small amount of cobalt (Co) must be uniformly formed on an exposed surface of the polysilicon layer. However, the Co layer is typically formed by a physical vapor deposition (hereinafter referred to as ‘PVD’) or similar method. Accordingly, the amount of cobalt (Co) deposited on a top surface of the polysilicon layer is much greater than the amount deposited on the sides of the polysilicon layer, thereby making it difficult to suppress the phenomenon.

### BRIEF SUMMARY

According to an embodiment of this disclosure, a metal ion blocking layer is selectively formed on only the top surface of a gate line having a relatively narrow critical dimension as compared to other gate lines. Thus, although a metal layer is subject to a phase change after being formed, the blocking layer functions to diffuse the metal ions of the metal layer only into the sides of the gate line, not into the top surface of the gate line. Accordingly, a phenomenon in which the gate line is bent or broken because of the shortage of Si ions can be prevented.

A method of manufacturing a semiconductor memory device according to an aspect of this disclosure comprises providing a semiconductor substrate, forming gate lines over the semiconductor substrate, wherein each of the gate lines has a stack structure comprising an upper layer having a blocking layer formed on a polysilicon layer, forming dielectric interlayers between the gate lines such that sides of the polysilicon layers of the gate lines are exposed, forming a metal layer on an entire surface of the dielectric interlayers, the blocking layers, and the polysilicon layers, causing the polysilicon layers of portions that contact the metal layer to undergo a phase change and become silicide layers, and removing the remaining unreacted metal layer.

A method of manufacturing a semiconductor memory device according to another aspect of this disclosure comprises providing a semiconductor substrate defining a cell region and a peripheral region, forming a gate insulating layer, a first polysilicon layer, a dielectric layer, and a second polysilicon layer over the semiconductor substrate, forming a blocking layer on the second polysilicon layer, patterning the layers to form a first gate line in the cell region and a second gate line in the peripheral region, forming a dielectric interlayer between the first and second gate lines, etching part of the dielectric interlayer to expose sides of the second polysilicon layers formed in the first and second gate lines, forming a metal layer on an entire surface of the dielectric interlayer, the blocking layers, and the second polysilicon layers, causing the second polysilicon layers that contact the metal layer to undergo a phase change and become silicide layers, and removing the remaining unreacted metal layer.

A method of manufacturing a semiconductor memory device according to yet another aspect of this disclosure comprises providing a semiconductor substrate defining a cell region and a peripheral region, forming a gate insulating layer, a first polysilicon layer, a dielectric layer, and a second polysilicon layer over the semiconductor substrate, forming a blocking layer on the second polysilicon layer, patterning the layers to form a first gate line in the cell region and a second gate line in the peripheral region, forming a dielectric interlayer between the first and second gate lines, removing the blocking layer on the second polysilicon layer formed in the second gate line, etching part of the dielectric interlayer to expose sides of the second polysilicon layers formed in the first and second gate lines, forming a metal layer on an entire surface of the dielectric interlayer, the blocking layers, and the second polysilicon layers, causing the second polysilicon layers that contact the metal layer to undergo a phase change and become silicide layers, and removing the remaining unreacted metal layer.

### BRIEF DESCRIPTION OF THE DRAWINGS

FIGS. 1A to 1J are cross-sectional views illustrating a method of manufacturing a semiconductor memory device according to the present disclosure.

### DESCRIPTION OF EMBODIMENT

An embodiment of the present disclosure is described in detail below with reference to the accompanying drawings. The drawing figures are provided to allow those having ordinary skill in the art to understand the scope of the embodiment of the disclosure.

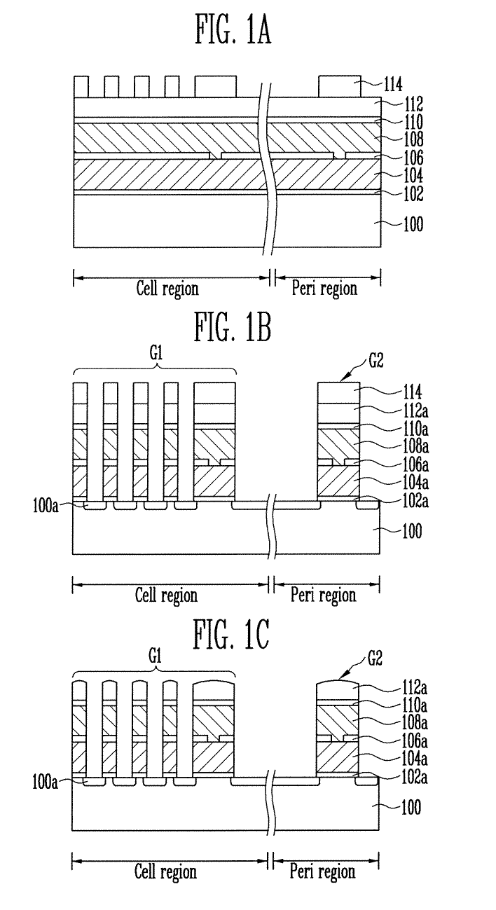

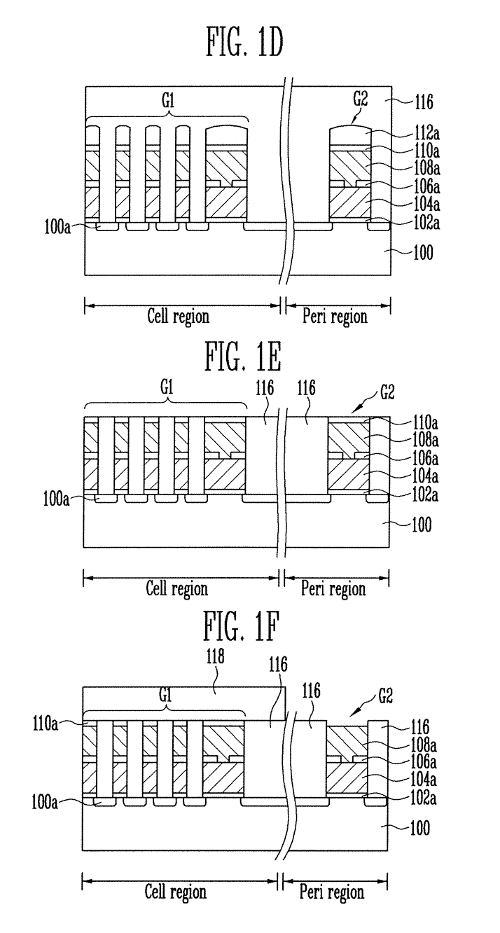

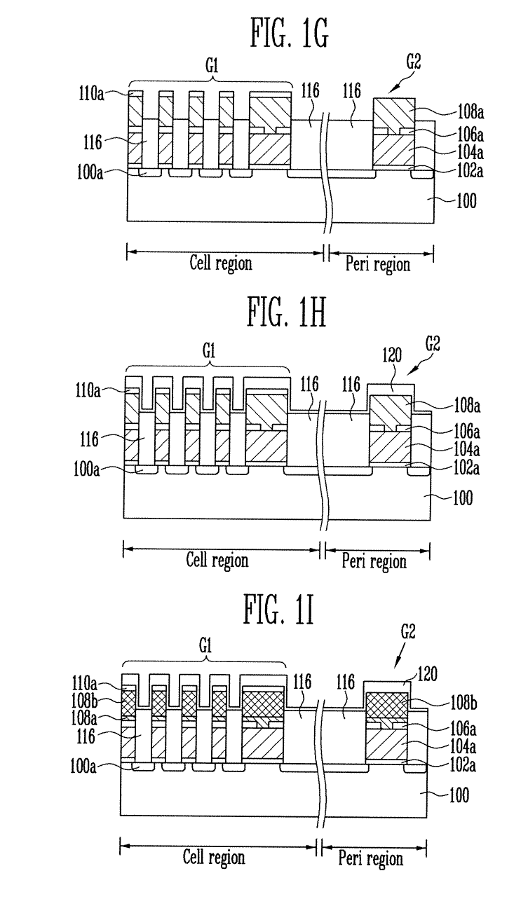

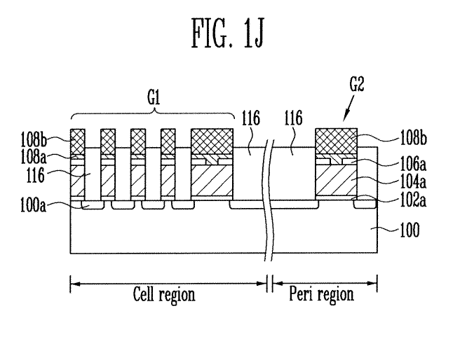

FIGS. 1A to 1J are cross-sectional views illustrating a method of manufacturing a semiconductor memory device according to the present disclosure.

Referring to FIG. 1A, a gate insulating layer 102, a first polysilicon layer 104, a dielectric layer 106, and a second polysilicon layer 108 are formed over a semiconductor substrate 100 that defines a cell region and a peripheral region. A blocking layer 110 is configured to prevent its metal ions from diffusing and is formed on the second polysilicon layer 108. A hard mask layer 112 and a first photoresist patterns 114 for gate lines are formed over the blocking layer 110.

The dielectric layer 106 preferably is formed by stacking an oxide layer, a nitride layer, and an oxide layer. Contact holes preferably are formed in regions in which switching elements are formed such that the first polysilicon layer 104 and the second polysilicon layer 108 are electrically connected to each other. The blocking layer 110 preferably comprises material that has a low diffusion reaction to a metal layer and can be easily removed. The blocking layer 110 preferably comprises, for example, nitride.

Referring to FIG. 1B, portions from the hard mask layer 112 to the gate insulating layer 102 are partially etched using the first photoresist patterns 114 as an etch mask, thereby forming first and second gate lines G1 and G2 in the cell region and the peripheral region, respectively. Herein, each of the first and second gate lines G1 and G comprises a stack of a hard mask pattern 112a, a blocking pattern 110a, a second polysilicon pattern 108a, a dielectric pattern 106a, a first polysilicon pattern 104a, and a gate insulating pattern 102a and has a different critical dimension. An ion implantation process is performed to form junctions 100a in the semiconductor substrate 100 exposed between the first and second gate lines G1 and G2.

The first gate line G1 formed in the cell region includes a plurality of cell gate lines and gate lines for selection elements. In each of the cell gate lines, the first polysilicon pattern 104a serves as a floating gate, and the second polysilicon pattern 108a serves as a control gate. In each of the gate lines for selection elements, the first polysilicon pattern 104a and the second polysilicon pattern 108a are connected to each other. The second gate line G2 formed in the peripheral region includes gate lines for high-voltage switching elements and low-voltage switching elements. In each of the gate lines for switching elements, the first polysilicon pattern 104a and the second polysilicon pattern 108a are connected to each other, thus serving as a gate electrode. In particular, the critical dimension of the second gate line G2 formed in the peripheral region is wider than that of the first gate line G1 formed in the cell region because of a difference in the level of a driving voltage.

Referring to FIG. 10, the first photoresist patterns 114 are removed. At this time, the hard mask pattern 112a can also be partially removed to have a lowered height.

Referring to FIG. 1D, a dielectric interlayer 116 is formed over the semiconductor substrate 100 including the first and second gate lines G1 and G2. The dielectric interlayer 116 preferably comprises oxide. Herein, to fully fill a gap between the first and second gate lines G1 and G2 with the dielectric interlayer 116, the dielectric interlayer 116 preferably covers all the hard mask patterns 112a.

Referring to FIG. 1E, part of the dielectric interlayer 116 and the hard mask patterns 112a are removed to expose the blocking pattern 110a at the top of the second gate line G2 formed in the peripheral region. The removal process preferably is performed using a chemical mechanical polishing (hereinafter referred to as ‘CMP’) process. Herein, the blocking patterns 110a at the top of the first gate line G1 formed in the cell region may not be exposed.

Referring to FIG. 1F, to remove the blocking pattern 110a at the top of the second gate line G2, a second photoresist pattern 118 through which the peripheral region is opened is formed on the first gate line G1 and the dielectric interlayer 116 of the cell region. The blocking pattern 110a at the top of the second gate line G2 is formed through an etch process using the second photoresist pattern 118 as an etch mask.

The etch process preferably is performed using an etchant having a high etch selectivity for the blocking pattern 110a relative to the second polysilicon pattern 108a and the dielectric interlayer 116.

Referring to FIG. 1G, the second photoresist pattern 118 is removed. The dielectric interlayer 116 is removed to a predetermined thickness using a blanket etch process, thereby exposing the sides of the second polysilicon patterns 108a of the first and second gate lines G1 and G2.

The blanket etch process preferably is performed until the sides of the second polysilicon patterns 108a are exposed to the maximum extent, but before, and preferably immediately before, the dielectric patterns 106a are exposed. This is because if the dielectric patterns 106a are exposed, they suffer etch damage and accordingly deteriorated device characteristics.

Referring to FIG. 1H, a metal layer 120 is formed on the entire surface of the dielectric interlayer 116, the second polysilicon patterns 108a, and the blocking patterns 110a. The metal layer 120 contacts only the sides of the second polysilicon patterns 108a because the blocking patterns 110a in the first gate line G1 have a narrow critical dimension, and contact the top surface and sides of the second polysilicon patterns 108a in the second gate line G2 having a wide critical dimension.

The metal layer 120 preferably is formed by depositing, for example, cobalt (Co) or other silicide-forming materials. The metal layer 120 preferably is formed using a plasma vapor deposition (PVD) or chemical vapor deposition (CVD) method. The metal layer 120 preferably is formed using a PVD method. In the case in which the metal layer 120 is formed using a PVD method, the metal layer 120 preferably is relatively thinner on the sides of the second polysilicon patterns 108a of the first and second gate lines G1 and G2 than on the exposed top surface thereof.

Referring to FIG. 1I, an annealing process is performed to diffuse the metal ions of the metal layer 120 into the second polysilicon patterns 108a. The second polysilicon patterns 108a into which the metal ions have been diffused undergoes a phase change by reacting with the metal layer 120, thus becoming silicide layers 108b. In the case in which the metal layer 120 is formed by depositing cobalt (Co), the silicide layer 108b becomes a CoSi₂ layer. Here, only part of the second polysilicon pattern 108a undergoes a phase change, thus becoming the silicide layer 108b.

In particular, as described above, the blocking patterns 110a are formed on the top surfaces of the second polysilicon patterns 108a formed in the first gate line G1 having a narrower critical dimension than the second gate line G2. Accordingly, in the first gate line G1, the metal ions of the metal layer 120 are not diffused from the top surfaces of the second polysilicon patterns 108a, but are diffused from only the sides of the second polysilicon patterns 108a. Consequently, an excessive phase change of the second polysilicon patterns 108a, formed in the first gate line G1, into the silicide layers 108b can be prevented, and so problems resulting from the shortage of Si ions can be prevented.

On the other hand, in the second gate line G2 having a wider critical dimension than the first gate line G1, the metal ions of the metal layer 120 are diffused into both the top surface and the sides of the second polysilicon pattern 108a. Accordingly, since the second polysilicon pattern 108a of the second gate line G2 can be sufficiently subject to a phase change into the silicide layer 108b, the resistance of a gate line can be improved.

To prevent the metal ions from exiting externally when the annealing process is performed, a protection layer can be further formed on the metal layer 120. The protection layer preferably is formed by depositing titanium (Ti) or titanium nitride (TiN) or both.

Referring to FIG. 1J, the blocking patterns 110a and the remaining unreacted metal layer 120 are removed. As described above, since an excessive phase change of the second polysilicon patterns 108a, formed in the first gate line G1, into the silicide layers 108b is prevented, the unreacted metal layer 120 uniformly remains. Accordingly, after the removal process is performed, a phenomenon in which gate lines are bent or broken can be prevented.

Meanwhile, although it has been illustrated in FIG. 1F that the blocking patterns 110a on the top surface of the second gate line G2 are removed using the second photoresist pattern 118, the processes up to FIG. 1J can be performed in a state in which the second photoresist pattern 118 is not formed and the blocking patterns 110a at the top of the first and second gate lines G1 and G2 are not removed. That is, the silicide layer 108b can be formed such that the metal layer 120 comes in contact with only the sides of the second polysilicon patterns 108a formed in the first and second gate lines G1 and G2 irrespective of the size of the critical dimension of the first and second gate lines G1 and G2.

The method of the present disclosure can improve the electrical properties of a gate line because the amount of metal ions diffused from the metal layer can be differently controlled depending on the size of the critical dimension of the gate line. In particular, a phenomenon in which the gate lines are bent or broken can be prevented, and an increase in the resistance of the gate line can be suppressed. Furthermore, since an increase in the resistance of the gate line can be suppressed, the reliability of a semiconductor memory device can be improved.

What is claimed is:

1. A method of manufacturing a semiconductor memory device, the method comprising:
providing a semiconductor substrate;
forming gate lines over the semiconductor substrate, each of the gate lines having a stack structure comprising an upper layer having a blocking layer formed on a polysilicon layer;
forming a dielectric interlayer between the gate lines such that sides of the polysilicon layers of the gate lines are exposed;
forming a metal layer on an entire surface of the dielectric interlayers, the blocking layers, and the polysilicon layers;
causing the polysilicon layers in contact with the metal layer to react with the metal layer to undergo a phase change and become silicide layers; and
removing an unreacted metal layer.

2. The method of claim 1, further comprising, before forming the polysilicon layer, forming the gate lines by sequentially stacking a gate insulating layer, a first polysilicon layer, and a dielectric layer over the semiconductor substrate.

3. The method of claim 1, wherein forming the dielectric interlayer between the gate lines such that sides of the polysilicon layers of the gate lines are exposed comprises:
forming the dielectric interlayer to fill a gap between the gate lines; and
etching a part of the dielectric interlayer to expose sides of the polysilicon layers of the gate lines.

4. The method of claim 1, wherein the gate lines have different critical dimensions.

5. The method of claim 4, wherein a gate line having a relatively wide critical dimension, from among the gate lines having the different critical dimensions, is a gate line for selection elements or high-voltage and low-voltage switching elements.

6. The method of claim 4, wherein a gate line having a relatively narrow critical dimension, from among the gate lines having the different critical dimensions, is a cell gate line.

7. The method of claim 4, further comprising, after forming the dielectric interlayer between the gate lines, removing the blocking layer on the polysilicon layer of a gate line having a relatively wide critical dimension, from among the gate lines.

8. The method of claim 1, further comprising removing the blocking layer after removing the unreacted metal layer.

9. The method of claim 1, wherein the blocking layer comprises nitride.

10. The method of claim 1, comprising forming the metal layer by depositing cobalt (Co).

11. The method of claim 1, comprising forming the silicide layers by annealing to diffuse metal ions of the metal layer into the polysilicon layers to cause a phase change of the polysilicon layers through a reaction of the metal ions of the metal layer and silicon (Si) ions of the polysilicon layer.

12. A method of manufacturing a semiconductor memory device, the method comprising:
providing a semiconductor substrate defining a cell region and a peripheral region;
forming a gate insulating layer, a first polysilicon layer, a dielectric layer, and a second polysilicon layer over the semiconductor substrate;
forming a blocking layer on the second polysilicon layer;
patterning the layers to form a first gate line in the cell region and a second gate line in the peripheral region;
forming a dielectric interlayer between the first and second gate lines;
etching a part of the dielectric interlayer to expose sides of the second polysilicon layers in the first and second gate lines;
forming a metal layer on an entire surface of the dielectric interlayers, the blocking layers, and the second polysilicon layers;
causing the second polysilicon layers in contact with the metal layer to react with the metal layer to undergo a phase change and become silicide layers; and
removing an unreacted metal layer.

13. The method of claim 12, further comprising removing the blocking layer after removing the unreacted metal layer.

14. The method of claim 12, wherein the blocking layer comprises nitride.

15. The method of claim 12, comprising etching the dielectric interlayer immediately before exposing the dielectric layer.

16. The method of claim 12, comprising forming the metal layer by depositing cobalt (Co).

17. The method of claim 12, comprising forming the silicide layers by annealing to diffuse metal ions of the metal layer into the second polysilicon layers to cause a phase change of the second polysilicon layers through a reaction of the metal ions of the metal layer and silicon (Si) ions of the second polysilicon layer.

18. A method of manufacturing a semiconductor memory device, the method comprising:
providing a semiconductor substrate defining a cell region and a peripheral region;
forming a gate insulating layer, a first polysilicon layer, a dielectric layer, and a second polysilicon layer over the semiconductor substrate;
forming a blocking layer on the second polysilicon layer;
patterning the layers to form a first gate line in the cell region and a second gate line in the peripheral region;
forming a dielectric interlayer between the first and second gate lines;
removing the blocking layer on the second polysilicon layer in the second gate line;
etching a part of the dielectric interlayer to expose sides of the second polysilicon layers in the first and second gate lines;
forming a metal layer on an entire surface of the dielectric interlayers, the blocking layers, and the second polysilicon layers;
causing the second polysilicon layers in contact with the metal layer to react with the metal to undergo a phase change and becoming silicide layers; and
removing an unreacted metal layer.

19. The method of claim 18, further comprising removing the blocking layer after removing the unreacted metal layer.

20. The method of claim 18, wherein the blocking layer comprises nitride.

21. The method of claim 18, comprising etching the dielectric interlayer immediately before exposing the dielectric layer.

22. The method of claim 18, comprising forming the metal layer by depositing cobalt (Co).

23. The method of claim 18, comprising forming the silicide layers by annealing to diffuse metal ions of the metal layer into the second polysilicon layers to cause a phase change of the second polysilicon layers through a reaction of the metal ions of the metal layer and silicon (Si) ions of the second polysilicon layer.
